(19) United States
(12) Patent Application Publication
(10) Pub. No.: US 2014/0354365 A1
(43) Pub. Date: Dec. 4, 2014

(54) Device for Compensating Temperature Drift of a VCO, and to a Method Thereof

(71) Applicant: Huawei Technologies Co., Ltd., Shenzhen (CN)

(72) Inventors: Peng Gao, Shanghai (CN); Yongquan Chen, Shanghai (CN); Bingxin Li, Kista (SE); Christian Grewing, Taby (SE)

(21) Appl. No.: 14/461,596

(22) Filed: Aug. 18, 2014

Related U.S. Application Data
(63) Continuation of application No. PCT/EP2012/055931, filed on Apr. 2, 2012.

(51) Int. Cl. H03L 1/02; H03L 5/00

(52) U.S. Cl. CPC H03L 1/023; H03L 5/00
USPC 331/70

(57) ABSTRACT

A device for compensating temperature drift of a voltage controlled oscillator (VCO) is provided. The VCO has at least one varactor arranged for controlling an output frequency f_{Out} of said VCO by applying a tuning voltage V_{Tune} and simultaneously applying a bias voltage V_{Bias} on a cathode and an anode of said at least one varactor, respectively. Said device comprises a monitoring circuit and a tuning circuit. Said monitoring circuit has an input arranged to receive said V_{Tune} and is arranged to monitor said V_{Tune} and further is arranged to activate said tuning circuit based on a value of said V_{Tune}, and said tuning circuit has an output connected to said anode and is arranged to output said V_{Bias}, wherein said tuning circuit further is arranged to tune said VCO by changing said V_{Bias} so as to compensate for a temperature drift of said VCO.

### CROSS-REFERENCE TO RELATED APPLICATIONS

This application is a continuation of International Application No. PCT/EP2012/055931, filed on Apr. 2, 2012, which is hereby incorporated by reference in its entirety.

### STATEMENT REGARDING FEDERALLY SPONSORED RESEARCH OR DEVELOPMENT

Not applicable.

### REFERENCE TO A MICROFICHE APPENDIX

Not applicable.

### TECHNICAL FIELD

The present invention relates to a device for compensating temperature drift of a voltage controlled oscillator (VCO) of a phased-locked loop (PLL) system, and to a method thereof.

### BACKGROUND

The PLL is commonly integrated on integrated circuits to generate frequency signals or clocks for on-chip or external systems. As an essential part of PLL, the VCO is also required to be integrated in the same chip. Due to the physical property of semiconductor components, the oscillating frequency will drift over temperature. When working in PLL, the VCO is locked to a certain frequency by negative feedback mechanism, which in turn modulates the control voltage of the VCO according to temperature variation.

In the PLL system, the control voltage of VCO always has limited range, and this range becomes narrower and narrower as the semiconductor technology evolves. If the control voltage goes out of the desired range, the negative feedback loop will go out of order and finally lose lock.

In communication systems, such as Global System for Mobile Communications (GSM), Universal Mobile Telecommunications System (UMTS), and Long Term Evolution (LTE), the PLL works as either the frequency source for radio frequency modules or the reference clock for data converters or baseband processors. The transmission will terminate if the PLL goes out of lock, which is disastrous for communication equipment. Some PLL systems have an implemented automatic recover circuit, which can pull the PLL back to lock state when it goes out of lock. But this kind of recover circuit is usually a reactive circuit and the PLL still fails to give correct output in a short time interval. For the communication system having very strict throughput requirements, even 100 microseconds (μs) interruption of transmission is intolerable.

According to a first prior art solution (U.S. 2008/0150641 A1), a temperature dependent voltage source is introduced as the preset bias point for coarse tuning. That means that the PLL is initially locked at a point which had relatively large headroom to tolerate the drift induced by temperature variation. Although this solution can bring PLL into an initial condition with quite a big margin to tolerate the temperature change, it is still not enough. Firstly, as the integrated circuit technology scales down, the VCO has to work under lower and lower supply voltage. Secondly, state-of-the-art low phase noise VCO often implements very low VCO gain, which means relatively large voltage range is required to compensate for specified frequency change. So, this solution is not suitable especially for low-voltage designs.

According to a second prior art solution (U.S. 2009/0261917 A1), an auxiliary varactor is employed which is controlled by a temperature dependent voltage source. As the temperature changes, the capacitance of the auxiliary varactor is also changed, and consequently the VCO frequency changes. The characteristic of the temperature dependent voltage source and auxiliary varactor is designed to pull the VCO frequency to the inversed direction of drifting induced by temperature, and helps to stabilize the control voltage of the main varactor of VCO. This solution works on the assumption that the temperature characteristic of VCO is already known. But it is quite difficult to accurately predict temperature property of VCO. This problem becomes even worse for wide band designs. Modern integrated wide band VCOs usually have multi sub-band topologies, and the temperature characteristics are much different from high-end to low-end frequencies. A lot of design effort is required to get the proper compensation coefficient for the whole frequency range, and because it works in open loop mode, this solution still suffers from the coefficient error due to the process spreading. In addition, the temperature dependent voltage source might be quite noisy influencing the VCO in the negative.

Hence, there is a need in the art for an improved solution to the problem of temperature drift of VCOs of PLLs.

### SUMMARY

An object of the present invention is to provide a solution which mitigates or solves the drawbacks and problems of prior art solutions. Another object of the invention is to provide a low cost, energy effective solution to the problem of temperature drift.

According to a first aspect of the invention, the above mentioned objects are achieved with a device for compensating temperature drift of a VCO in a PLL, said VCO having at least one varactor arranged for controlling an output frequency f_{Out} of said VCO by applying a tuning voltage V_{Tune} and simultaneously applying a bias voltage V_{Bias} on a cathode and an anode of said at least one varactor, respectively; said device comprising a monitoring circuit and a tuning circuit: said monitoring circuit having an input arranged to receive said tuning voltage V_{Tune} and being arranged to monitor said tuning voltage V_{Tune} and further being arranged to activate said tuning circuit based on a value of said tuning voltage V_{Tune}; and said tuning circuit having an output connected to said anode and being arranged to output said bias voltage V_{Bias}, wherein said tuning circuit further is arranged to tune said VCO by changing said bias voltage V_{Bias} so as to compensate for a temperature drift of said VCO.

Different embodiments of the above device are disclosed in the appended dependent claims.

According to a second aspect of the invention, the above mentioned objects are achieved by a method for compensating temperature drift of a VCO in a PLL, said VCO having at least one varactor arranged for controlling an output frequency f_{Out} of said VCO by applying a tuning voltage V_{Tune} and simultaneously applying a bias voltage V_{Bias} on a cathode and an anode of said at least one varactor, respectively; said method comprising the steps of:

a) monitoring said tuning voltage V_{Tune}; and

b) tuning said VCO by changing said bias voltage V_{Bias} based on a value of said monitored tuning voltage V_{Tune} so as to compensate for a temperature drift of said VCO.

The present invention solves the temperature drifting problem of VCO in PLL systems with less size of integrated circuit chip area, less power consumption, and less sacrifice of phase noise to prior solutions. The present solution also means that the cost for producing the chip can be held low. Moreover, the present solution is more reliable compared to prior art solutions.

Further applications and advantages of the invention will be apparent from the following detailed description.

### BRIEF DESCRIPTION OF THE DRAWINGS

The appended drawings are intended to clarify and explain different embodiments of the present invention in which:

FIG. 1 schematically shows a PLL comprising a compensation circuit according to the invention;

FIG. 2 schematically shows the compensation circuit in more detail;

FIG. 3 schematically shows an alternative solution with an auxiliary varactor according to the invention; and

FIG. 4 shows simulation results for the present invention.

### DETAILED DESCRIPTION

To achieve the aforementioned and other objects, the present invention relates to a device for compensating temperature drift of a VCO in a PLL. The VCO is of the type having at least one varactor arranged for controlling an output frequency f_{Out} of the VCO by the application of a tuning voltage V_{Tune} and simultaneous application of a bias voltage V_{Bias} on a cathode and an anode of the at least one varactor, respectively. The device further comprises a monitoring circuit and a tuning circuit. The monitoring circuit has an input arranged to receive the tuning voltage V_{Tune} and is arranged to monitor the tuning voltage V_{Tune}. The monitoring circuit is further arranged to activate the tuning circuit based on a value of the monitored tuning voltage V_{Tune}. The tuning circuit has an output connected to the anode of the varactor and is arranged to output the bias voltage V_{Bias}. The tuning circuit is further arranged to tune the VCO by changing the bias voltage V_{Bias} so as to compensate for a temperature drift of the VCO.

Thereby, a closed loop solution to the problem of temperature drift of VCOs is provided. Since the present temperature compensation circuit works in closed loop, as it monitors the VTUNE and tune according to the value of VTUNE, it provides a more reliable solution compared to open-loop solutions. The present invention can therefore advantageously prevent the PLL from losing of lock due the ambient temperature variation, and guarantee the normal operation of the communication equipment in various working conditions. Furthermore, with the present invention the chip size needed can be held small which means that the cost of the chip is also low. Moreover, the compensation circuit can be formed of comparators and low-current charge-pump resulting in low power consumption.

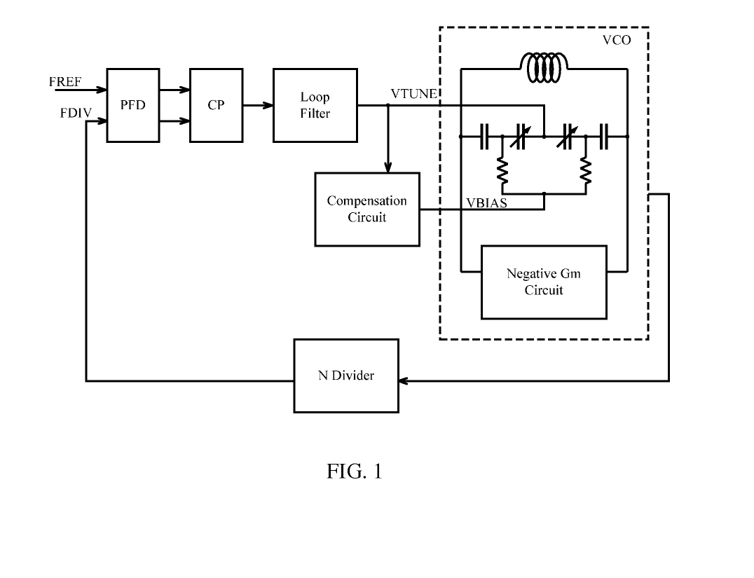

The state-of-the-art low phase noise consists of inductor-capacitor (LC) resonate tank and loss compensation circuits. The frequency of the VCO is controlled by tuning the capacitance of the resonant tank, i.e. the relative voltage between anode and cathode of the varactor. Usually, the anode of the varactor is tied to a fixed potential, such as ground, and the cathode is tuned by the output voltage of Loop Filter in PLL, i.e. VTUNE in FIG. 1. The voltage on VTUNE is not infinite, especially for modern sub-micron integrated circuits technology, where the operation voltage become lower and lower. Consequently, the voltage range of VTUNE will become narrower due to the limitation of charge pump, as well as the effective range of varactors.

In principle, the negative feedback mechanism of PLL will force VTUNE to a certain voltage that can make VCO output required frequency. With the help of state-of-the-art wide band VCO techniques, the VTUNE voltage can be set to some ideal value. Actually, the capacitance and parasitic capacitance of varactor or other semiconductor components is variable over temperature. That means, with fixed VTUNE voltage, the VCO frequency will be drifting over temperature. But the feedback loop will force frequency to be stable, in other words, the VTUNE voltage has to drift to keep this stability as temperature is changing. If this voltage goes out of limited range, the PLL will fail to lock.

FIG. 1 schematically shows a PLL circuit having a VCO. The PLL also comprises a compensation circuit according to the invention. The idea is to control the relative voltage between both ends of varactor instead of controlling only one end of the varactor. If the VTUNE voltage goes out of desired range, the compensation circuit will respond to this and tune the VBIAS voltage, and consequently the capacitance of the varactor.

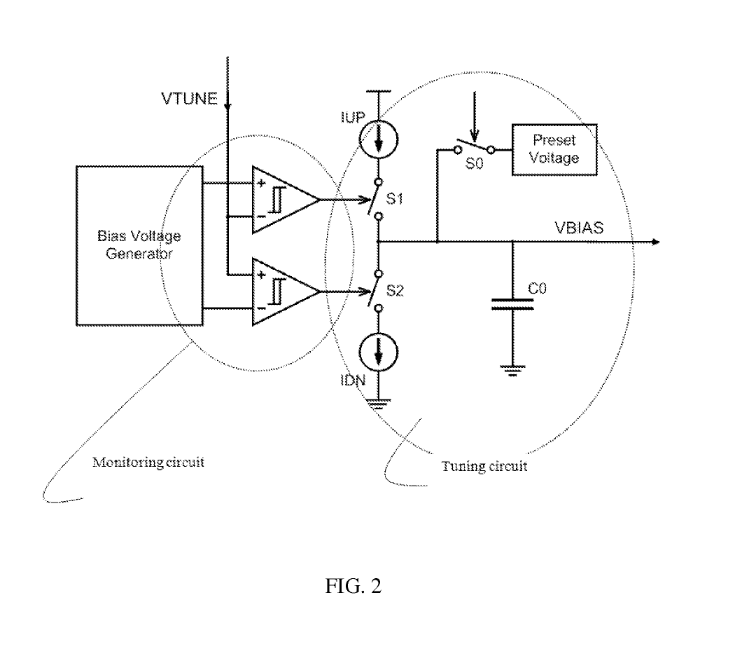

An embodiment of the compensation circuit is shown in FIG. 2. The compensation circuit comprises two main parts, namely a monitoring circuit and a tuning circuit. The monitoring circuit monitors VTUNE voltage and the tuning circuit outputs the VBIAS voltage so as to compensate for a temperature drift of the VCO. The tuning circuit is activated based on a value of the VTUNE.

As seen in FIG. 2, the monitoring circuit comprises two comparators, i.e. first and second comparators which on a first side are connected so as to receive VTUNE. The comparators are further on a second side connected to first S1 and second S2 switches, respectively. The comparators are so arranged that they activate associated switches S1, S2 if the value of VTUNE is less than a first threshold for the first comparator or greater than a second threshold for the second comparator. Preferably, the comparators are hysteretic comparators implying that the first and second thresholds are hysteresis threshold values. Hysteretic comparators have two threshold voltages, e.g. VTH1 and VTH2 wherein VTH2 is greater than VTH1. If the second comparator is used in the example; when the voltage value of VTUNE is rising up, the second comparator will output a logical “1” if the voltage of VTUNE is greater than VTH2, but when the voltage of VTUNE is falling down, the second comparator will output a logical “0” if the voltage of VTUNE is lower than VTH1. The advantage of using hysteretic comparators is to avoid too frequent activation/deactivation of the tuning circuit since two thresholds are used per comparator. If normal comparators are used (having only one threshold), there is a risk that the tuning circuit is activated/deactivated too often if the value for VTUNE is drifting around the threshold value resulting in unstable behavior of the compensation circuit.

Depending on which of the switches that is activated, the capacitor C₀ of the tuning circuit is charged or discharged, thereby controlling VBIAS. The charging or discharging is performed by a so called charge pump circuit of the tuning circuit. In FIG. 2, the charge pump is formed by a current source IUP and a current sink IDN connected in series with the first S1 and second S2 switches. It is also noted that the current sink IDN is connected to ground and that the first S1 and second S2 switches are connected between the current source IUP and the current sink IDN in this embodiment.

As mentioned, generally the voltage of VBIAS is controlled by injecting or dissipating charges on capacitor C₀. This charge domain operation is accomplished by a charge pump circuit controlled by the hysteretic comparators.

During acquisition process of the PLL (starts operating before the coarse tuning system), the VBIAS voltage is preset to a certain voltage by the use of the preset voltage circuit shown in FIG. 2. Thereafter, if the VTUNE voltage goes higher than threshold value, the switch S2 will be closed and the charges on C₀ will be dissipated to pull VBIAS voltage lower. Consequently, the VTUNE voltage will follow VBIAS to go down and return to the desired window. Similar but reversed operation will be taken if VTUNE goes down due to temperature change.

By well designed IUP and IDN current and C₀ capacitance, the bandwidth of this compensation circuit will be controlled low enough to keep the PLL tracking this variation. Since it can be controlled by current, the size of the capacitor can be cut down significantly which is advantageous. When the tuning circuit is active, the charge pump will charge or discharge the capacitor C₀, thereby changing the bias voltage VBIAS. The changing speed of VBIAS is proportional to the charge pump current IUP or IDN, and anti-proportional to the capacitance of capacitor C₀. In the PLL system, it is important to keep the changing speed of VBIAS to a reasonable low level, in order not to disturb the operation of the whole system. Here, this characteristic can be described as bandwidth: the wider the bandwidth, the faster the changing speed of VBIAS, and vice versa. In order to keep the changing speed of VBIAS low either the charge pump current IUP or IDN can be lowered, or the capacitance C₀, can be increased. Usually, it is desired to lower down the current value in order to make the capacitance C₀ as small as possible, because the capacitor will take relatively large area on the chip, and therefore increase the cost. However, the minimum current of IUP and IDN is limited by the semiconductor device's property, and hence the capacitance C₀ must have a proper value to keep the changing speed of VBIAS low enough.

According to another embodiment of the invention when the PLL works as desired, the charge pump is not active which means that the noise contributed by the compensation circuit is null. Hence, the tuning circuit is arranged to operate in an active mode or in a passive mode in which the charge pump circuit is not active. When the circuit works in charging or discharging active mode, the noise from current source or current sink is very low if the IUP/IDN are designed very small to reduce the size of C₀ . In addition, the capacitor C₀ works as an integrator of current, and the noise at high frequency will be attenuated. Since the PLL can attenuate the low frequency noise of VCO, noise at high frequency offset is more attractive for VCO design.

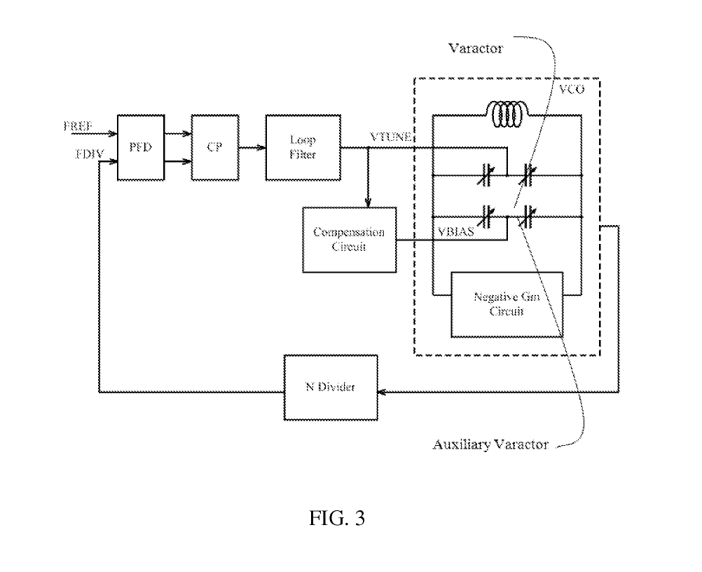

For some VCO designs, the back side of the varactor needs to be connected to some fixed potential point, for instance ground or power supply. If this is the case, an auxiliary varactor can be introduced to tuning the capacitance of the resonate tank, as shown in FIG. 3. Instead of changing the capacitance of the main varactor, the tuning of the auxiliary varactor can give the same function.

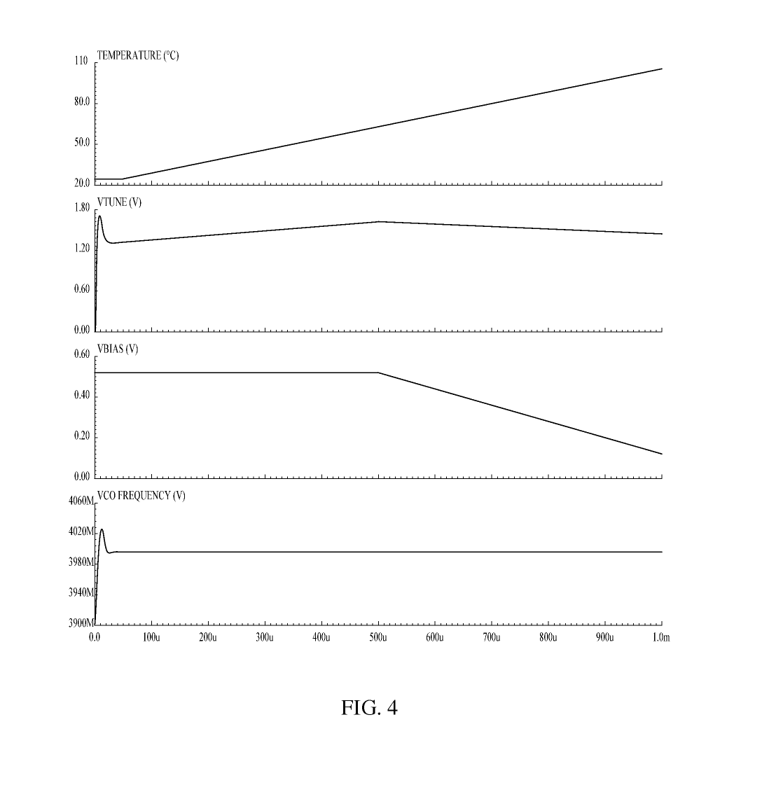

To verify the functionality of the present solution, system level simulations have been performed with the behavior model constructed by Verilog-A language. The simulation result is given in FIG. 4. As shown, as the temperature goes high the VTUNE voltage rises until a threshold is reached, and the charge pump is activated to pull down the VBIAS voltage by discharging the capacitor C₀. In consequence, the VTUNE voltage will be kept in an acceptable region in spite of the continuous rising of temperature. It is also found that, the VCO output frequency is quite stable during the whole process, which means that no interruption is induced by this solution.

Furthermore, the invention also relates to a corresponding method comprising the steps of: monitoring a tuning voltage V_{Tune} for a VCO of a PLL; and tuning the VCO by changing the bias voltage V_{Bias} based on a value of the monitored tuning voltage V_{Tune} so as to compensate for a temperature drift of the VCO. The method can be modified to e.g. comprise further steps corresponding to different embodiments, mutatis mutandis, of the device described above.

Finally, it should be understood that the present invention is not limited to the embodiments described above, but also relates to and incorporates all embodiments within the scope of the appended independent claims.

What is claimed is:

1. A device for compensating temperature drift of a voltage controlled oscillator (VCO) in a phased locked loop (PLL), said VCO having at least one varactor arranged for controlling an output frequency f_{Out} of said VCO by applying a tuning voltage V_{Tune} and simultaneously applying a bias voltage V_{Bias} on a cathode and an anode of said at least one varactor, respectively, wherein said device comprises:
a monitoring circuit; and
a tuning circuit,
wherein said monitoring circuit has an input arranged to receive said tuning voltage V_{Tune} and is arranged to monitor said tuning voltage V_{Tune} and further is arranged to activate said tuning circuit based on a value of said tuning voltage V_{Tune},
wherein said tuning circuit has an output connected to said anode and is arranged to output said bias voltage V_{Bias}, and
wherein said tuning circuit further is arranged to tune said VCO by changing said bias voltage V_{Bias} to compensate for a temperature drift of said VCO.

2. The device according to claim 1, wherein said monitoring circuit comprises a first comparator and a second comparator connected with said input of said monitoring circuit for monitoring said tuning voltage V_{Tune}.

3. The device according to claim 2, wherein said tuning circuit is activated by means of said first and second comparators and associated first and second switches, respectively.

4. The device according to claim 3, wherein said tuning circuit is activated when said tuning voltage V_{Tune} is less than a first threshold for said first comparator or greater than a second threshold for said second comparator.

5. The device according to claim 4, wherein said first and second comparators are hysteretic comparators and said first and second thresholds are hysteresis threshold values.

6. The device according to claim 1, wherein said tuning circuit comprises a capacitor C₀ and a charge pump circuit connected with said output of said tuning circuit, and wherein said charge pump circuit is arranged to control said bias voltage V_{Bias} by charging or discharging said capacitor C₀.

7. The device according to claim 3, wherein said charge pump circuit comprises a current source and a current sink connected in series with said first and second switches, and wherein said current sink is connected to ground and said first and second switches are connected between said current source and said current sink.

8. The device according to claim 7, wherein said output of said tuning circuit is connected in-between said first and second switches.

9. The device according to claim 6, wherein said tuning circuit further comprises a preset voltage generator.

10. The device according to claim 9, wherein a voltage over said capacitor C₀ is preset by said preset voltage generator when said PLL starts operating before a coarse tuning system of said PLL starts.

11. The device according to claim 1, wherein said tuning circuit is arranged to work in both a passive mode in which said charge pump circuit is not active, and in an active mode in which said charge pump circuit charges or discharges said capacitor C₀.

12. The device according to claim 7, wherein said passive mode is achieved when said first and second switches are open, and wherein said active mode is achieved when only one of said first or second switches is closed.

13. The device according to claim 1, wherein said at least one varactor is an auxiliary varactor connected in parallel with at least one further varactor of said VCO.

14. A method for compensating temperature drift of a voltage controlled oscillator (VCO) in a phased locked loop (PLL), said VCO having at least one varactor arranged for controlling an output frequency f_{Out} of said VCO by applying a tuning voltage V_{Tune} and simultaneously applying a bias voltage V_{Bias} on a cathode and an anode of said at least one varactor, respectively, wherein the method comprises:
monitoring said tuning voltage V_{Tune}; and
tuning said VCO by changing said bias voltage V_{Bias} based on a value of said monitored tuning voltage V_{Tune} to compensate for a temperature drift of said VCO.
